(19) United States
(12) Patent Application Publication
(10) Pub. No.: US 2026/0172010 A1
(43) Pub. Date: Jun. 18, 2026

(54) USING THROTTLER FOR DROOP MITIGATION

(71) Applicant: Arm Limited, Cambridge (GB)

(72) Inventors: Mahadevamurty NEMANI, San Diego, CA (US); Amit CHHABRA, Noida (IN); Rainer HERBERHOLZ, Great Abington (GB)

(21) Appl. No.: 18/982,337

(22) Filed: Dec. 16, 2024

(51) Int. Cl. H03K 5/01; G06F 1/08

(52) U.S. Cl. CPC H03K 5/01; G06F 1/08

(57) ABSTRACT

A clock throttler circuit for droop mitigation and disclose circuitry, related methods and state machine, the method performed at a system to select a first clock signal or a second clock signal to be provided to a subsystem, the method including: receiving, from a droop detector, a trigger signal indicative of a droop event at the subsystem; invoking modulation circuitry to throttle the selectable clock signal in accordance with the event; selecting the first clock signal; providing, to the modulation circuitry, the first clock signal to be throttled.

### TECHNICAL FIELD

The present techniques relate to using a clock throttler circuit for droop mitigation. In particular, the present techniques relate to circuitry, related methods and state machine therefor.

### BACKGROUND

Some computer units (e.g. a central processor unit (CPU) or graphics processor unit (GPU)) may experience performance issues due to droop events.

There is a need for mitigation action to address such performance issues.

### SUMMARY

The present techniques relate to addressing or mitigating such performance issues or improving known mitigation techniques.

According to a first aspect, there is provided a method of droop mitigation, the method performed at a system to select a first clock signal or a second clock signal to be provided to a subsystem, the method comprising: receiving, from a droop detector, a trigger signal indicative of a droop event at the subsystem; invoking, responsive to the trigger signal, modulation circuitry to throttle the selectable clock signal in accordance with the event; selecting the first clock signal; providing, to the modulation circuitry, the first clock signal to be throttled.

According to a further aspect there is provided a method of droop mitigation, the method performed at a system to throttle a clock signal, the method comprising: receiving, from droop mitigator circuitry, a request to apply a target throttle rate; receiving, from the droop mitigator circuitry, the clock signal; applying a first throttle rate to the received clock signal; providing the clock signal with the first throttle rate to a subsystem.

Circuitry to perform droop mitigation, the circuitry comprising: a first component configured to: receive, from a second component, a request to apply a target throttle rate; receive, from the second component, a clock signal; apply a first throttle rate to the received clock signal; provide the clock signal with the first throttle rate to a subsystem.

According to a further aspect, there is provided a system comprising: the above circuitry, implemented in at least one packaged chip; at least one system component; and a board, wherein the at least one packaged chip and the at least one system component are assembled on the board.

According to a further aspect, there is provided a chip-containing product comprising the above system assembled on a further board with at least one other product component.

According to a further aspect, there is provided a non-transitory computer-readable medium to store computer-readable code for fabrication of the above circuitry.

### BRIEF DESCRIPTION OF THE DRAWINGS

Embodiments of the present techniques will now be described by way of example only and with reference to the accompanying drawings, in which:

FIG. 1 schematically shows a block diagram of a system for droop mitigation comprising modulation based mitigator circuitry and droop mitigator circuitry in accordance with an embodiment of the present techniques;

FIG. 2 schematically shows clock throttler circuitry of the modulation based mitigator circuitry of FIG. 1;

FIG. 3 schematically shows example patterns in accordance with the present techniques;

FIG. 4 schematically shows the operations of a first state machine of the droop mitigator circuitry of FIG. 1 in accordance with the present techniques;

FIG. 5a schematically shows a simplified flow diagram of a method of operation of the system of FIG. 1 according to an implementation of the present techniques;

FIG. 5b schematically shows a simplified flow diagram of a method of operation of the system of FIG. 1 according to an implementation of the present techniques;

FIG. 6a schematically shows a waveform diagram for invoking the clock throttler circuitry of FIG. 1 according to an implementation of the present techniques;

FIG. 6b schematically shows a waveform diagram for invoking the clock throttler circuitry of FIG. 1 according to an implementation of the present techniques;

FIG. 7 schematically shows a signal diagram in accordance with the present techniques;

FIG. 8 illustrates a system and a chip-containing product in accordance with the present techniques.

### DETAILED DESCRIPTION

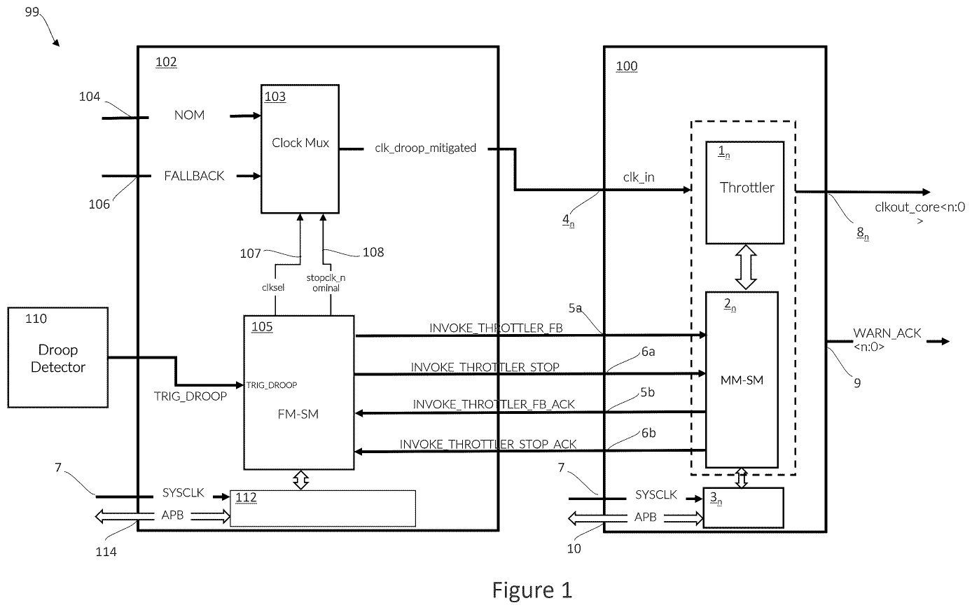

FIG. 1 schematically shows a block diagram of system 99 for droop mitigation comprising modulation based mitigator circuitry 100 (hereafter “modulation circuitry” 100) and droop mitigator circuitry 102.

The modulation circuitry 100 comprises one or more clock throttler circuits 1ₙ, one or more mitigation state machines 2₁ to control the one or more clock throttler circuits and storage circuitry 3, which in the illustrative example of FIG. 1 comprises a register bank 3 comprising a plurality of registers.

The modulation circuitry 100 comprises various input and outputs to receive/provide signals (e.g. from external hardware and/or software components).

It will be appreciated that the term “signal” is non-limiting and may take any form to convey a message, operation or information to a component (hardware or software), where, for example, the signal may comprise one or more bits, a logic value (e.g. high or low), or a voltage value etc. In embodiments the signal may comprise a clock signal having a particular frequency and or level (e.g. voltage level).

Furthermore, the signals provided to a component (e.g. hardware or software) to control the operation thereof (E.g. to select a particular clock signal) or to change properties thereof (e.g. to cause the component to operate in a certain way) may be referred to as a “control signal.”

In FIG. 1, modulation circuitry 100 comprises:
i. Input 4 to receive clock input signal (clkin) which in the present
illustrative example comprises a droop mitigated clock signal from the droop mitigator circuitry 102;
ii. Input 5a to invoke a fallback setting at the clock throttler circuitry;
iii. Output 5b to provide a fallback clock setting acknowledgment responsive to a first droop event;
iv. Input 6a to invoke a stop clock setting at the clock throttler circuitry responsive to a second droop event;
v. Output 6b to provide a stop clock setting acknowledgment;
vi. Input 7 to receive a system clock signal (SYSCLK), which is provided to the one or more mitigation state machines 2₁ and storage 3; The system clock signal (SYSCLK) may be a relatively low frequency clock signal compared to clock input signal (clkin);
vii. Output 8 to provide a clock output signal “clkout_core <n:0> from each clock throttler circuit 1₁, and where each “clkout_core <n:0> may be provided to a subsystem (e.g. a CPU, GPU, NPU etc.);
viii. Output 9 comprising a warning acknowledgement signal “WARN_ACK,” which may be used for handshaking purposes;
ix. Interface 10, such as an Advanced Peripheral Bus (APB), which may be part of the Advanced Microcontroller Bus Architecture (AMBA) protocol family, although the claims are not limited in this respect.

The inputs/outputs and the operation of the modulation circuitry 100 are

described in detail below. It will also be appreciated that additional inputs/outputs, or alternative inputs/outputs, may also be provided and the modulation circuitry 100 is not limited to those depicted in FIG. 1.

In FIG. 1, droop mitigator circuitry 102 comprises clock selection circuitry 103 (depicted as multiplexer circuitry) to select, responsive to a clock select signal (clksel) 107 from state machine circuitry 105, a NOMINAL clock signal 104 or a FALLBACK clock signal 106 as the droop mitigated clock (clk_droop_mitigated) signal 4. The NOMINAL clock signal has a higher clock frequency relative to the FALLBACK frequency and is selected as the droop mitigated clock (clk_droop_mitigated) signal 4 when no droop event is detected and the FALLBACK clock signal is selected when a droop event is detected. The droop mitigator circuitry 102 receives a droop trigger signal (TRIG_DROOP) from droop detector circuitry which is to monitor for a droop event (e.g. at a subsystem).

The clock selection circuitry 103 can also, responsive to a clock select signal (clksel) 107 from state machine circuitry 105 pause (or gate) the pulses of the nominal clock, where rather than providing the FALLBACK clock when a droop event is detected, the NOMINAL clock signal is paused (or gated) such that the droop mitigated clock has no clock pulses (STOP).

The clksel signal 107 may select neither the NOMINAL clock signal 104 nor the FALLBACK clock signal 106 when a particular droop event is detected for which the FALLBACK clock is not sufficient to mitigate the consequences of the event (i.e. to ensure correct execution of the subsystem at which the event was detected). Such an event may be a sign-off violation event resulting from a brown-out from the power-source. Alternatively, when a circuit is operating at a lower bound of an acceptable voltage margin, any droop may trigger a sign-off violation, as any drop in voltage risks causing hold-timing failures as opposed to set-up timing failures which may be addressed by frequency reduction. In response to a sign-off violation event, the clock signal activity may be stopped.

The droop mitigator circuitry 102 comprises storage register bank 112 to receive the system clock signal (SYSCLK) 7 and external communications via the interface 114, where the registers of the register bank 112 may be accessed by, for example, firmware, via the interface 112. For example, the register bank 112 may store data which is used to control the state machine 105.

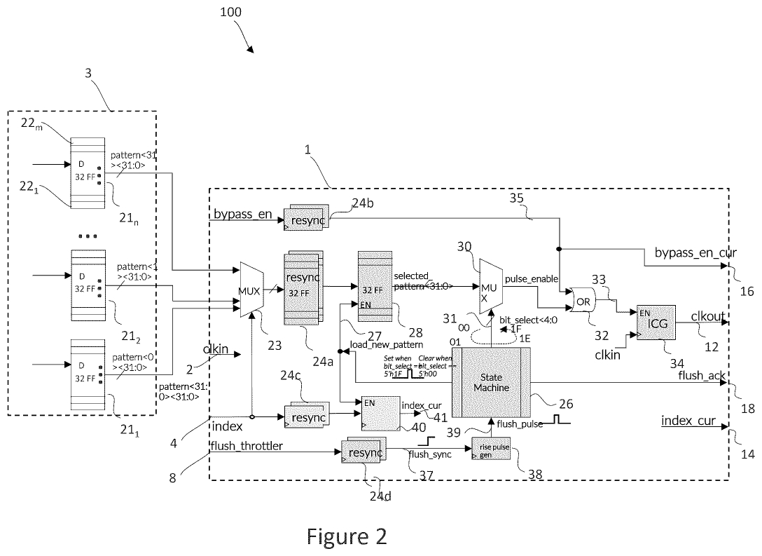

FIG. 2 is a schematic diagram showing the clock throttler circuitry 1ₙ in more detail. The system 99 also shows the register bank 3 in more detail, where in the present illustrative examples the register bank 3 comprises a plurality of n-bit registers 21₁ to 21ₙ, where each register is to store a plurality of bits 22₁ to 22ₘ. In the present illustrative example, each register is to store 32-bits, where each bit corresponds to a single bit of a 32-bit pattern as will be described in detail below.

As depicted in FIG. 2, first selection circuitry 23 (depicted as first multiplexer circuitry in FIG. 2), selects a pattern from one of the registers 21₁ to 21ₙ responsive to the index signal received from the mitigation state machine (not shown in FIG. 2). The pattern defines the throttle amount or rate (hereafter “throttle rate”) to be applied by the clock throttler circuit. The index signal may be received from the mitigation state machine responsive to an event that requires clock throttling for a particular subsystem (e.g. overcurrent event; overtemperature event).

The registers 21₁ to 21ₙ that store the respective patterns may be in a first clock domain (e.g. a relatively low frequency system clock (SYSCLK) domain) whereas at least some of the logic of the clock throttler circuitry 1 may be in a second clock domain (e.g. a relatively high frequency clock input (clkin) domain). Therefore, synchronisation (“resync”) circuitry 24a-d is provided to synchronise the input signals from the first clock domain to the second clock domain.

In FIG. 2, the selected pattern is provided from the first selection circuitry 23 to synchronisation circuitry 24a, where the synchronisation circuitry 24a comprises storage depicted as a register 24a to store the bits of the selected pattern therein. Then the selected pattern in the synchronisation circuitry 24a is provided to the selected pattern register 28 responsive to a first enable signal 27 (“load_new_pattern”) received at the selected pattern register 28 from the state machine 26.

Second selection circuitry 30 (depicted as second multiplexer circuitry in FIG. 2a) selects, responsive to a particular value of “bit_select <4:0>” dentifier signal 31, a particular bit of the pattern stored at the bit location/address in the selected pattern register 28 corresponding to the value of the “bit_select <4:0>” signal. The “bit_select <4:0>” signal 31 identifies a single bit location/address at the selected pattern register 28, where the state machine 26 provides bit_select <4:0> signals 31 in a successive or sequential manner. As an illustrative example, the second selection circuitry 30 will firstly select bit 0 of the pattern responsive to a first bit_select <00> signal, then select bit 1 of the stored pattern responsive to a next bit_select <01> signal, then select bit 2 of the stored pattern responsive to bit_select <02> signal and continue up to bit 31 responsive to bit_select <1F> signal, where all 32 bits are individually selected and successively passed to the logic gate 32 (i.e. responsive to an incremental sequence of bit_select <4:0> signals). Alternatively, the second selection circuitry 30 may firstly select bit 31 and then, in a decremental sequence responsive to bit_select <4:0> signals individually select all 32 bits, and successively pass them to the logic gate 32 (i.e. responsive to an decremental sequence of bit_select <4:0> signals). Other sequences may also be envisaged.

The second selection circuitry 30 provides the bit selected responsive to a particular bit_select <4:0> signal 31 to the logic gate 32, and the individual bits are successively provided from the logic gate 32 as a pulse enable signal 33 to integrated clock gate (ICG) circuitry 34. The logic gate 32 is depicted as an OR gate in FIG. 2a, although the claims are not limited in this respect.

The ICG circuitry 34 receives the clock input signal (clkin), which comprises a plurality of pulses, and, responsive to applying the pulse enable signal 33, passes or gates successive pulses of the clock input signal (clkin) to provide the clock output (clkout) 12 dependent on the value of the pulse enable signal 33 applied at the ICG circuitry. For example, the ICG circuitry 34 may pass a pulse of the clock input signal when the applied pulse enable signal is high (or 1) such that the pulse of the clock input signal (clkin) is passed and output in the clock output signal (clkout) 12. As a further example, the ICG 34 may gate a pulse of the clock input signal (clkin) when the applied pulse enable signal is low (or 0) such that pulse of the clock input signal (clkin) is not output in the clock output signal (clkout). Thus, gating pulses of the clock input signal (clkin) means that the clock output signal (clkout) will have fewer pulses than the clock input signal (clkin). A clock output signal having fewer pulses than a corresponding clock input signal (clkin) is taken to be a throttled version of the clock input signal (clkin) i.e. throttled

The various patterns and signals may be used to control how the clock throttler circuitry 1ₙ throttles (i.e. the throttle rate) the clock output signal (clkout) 8₁ responsive to an event, such as an overcurrent event or an overtemperature event.

Thus, the clock throttler circuitry 1 can generate a throttled clock output signal (clkout) 8₁ which may be provided to a subsystem (e.g. CPU, GPU or NPU).

The logic gate 32 also receives bypass enable signal (bypass_en) 35 to bypass the first and second selection circuitry and prevent throttling. The bypass enable signal 35 may, when asserted (e.g. set to high (or 1)) cause the ICG 34 circuitry to pass all pulses of the clock input signal (clkin) irrespective of the pulse enable signal 33, which means that all pulses of the clock input signal (clkin) will be passed and provided as the clock output signal (clkout), so the clock output signal (clkout) will not be throttled. Such bypass functionality may be provided for a test sequence or responsive to a particular user requirement.

The logic gate 32 is optional, and in an alternative embodiment, the individual bits of the selected pattern may be passed from the second selection circuitry 30 directly to the ICG circuitry 34.

As the bits of the pattern selected responsive to bit_select <4:0> signals are provided as the enable signal for the ICG circuitry 34, the ICG circuitry 34 passes or gates the pulses of the clock input signal (clkin) responsive to applying the bits of the pattern selected responsive to bit_select <4:0> signals.

In embodiments, an event (or application or user) may require a new pattern to be applied rather than waiting for the state machine 26 to complete the cycle of bit_select <4:0> signals for a current pattern.

The first selection circuitry 23 may select the new pattern from one of the registers 211 to 21n responsive to a new “index” signal received at input 4 identifying the new pattern and is provided to register 24a to store the bits of the selected new pattern.

To flush the current pattern from the selected pattern register a “flush_throttler” signal may be asserted (e.g. when set to 1 by the mitigation state machine not shown in FIG. 2). The “flush_throttler” signal is synchronised to the clock input signal (clkin) clock domain at synchronisation circuitry 26d and provided as a “flush_sync” signal 37 to rise pulse generation circuitry 38. Responsive to the “flush sync” signal the rise pulse generation circuitry 38 generates a “flush_pulse” signal 39 and provides the “flush_pulse” signal 39 to the state machine 26.

Responsive to the “flush_pulse” signal 39 being asserted (e.g. for at least one clock cycle), the state machine 26 increments the value of the bit_select <4:0> signal to correspond to a location identifying a final bit of the selected pattern to be applied (e.g. bit 32 of a 32-bit pattern) and also provides a “load_new_pattern” pulse. The state machine 26 also asserts (e.g. sets to 1) a flush acknowledgement signal (“flush_ack”), and when the “flush_sync” signal is deasserted or cleared (e.g. when set to 0) the state machine 26 deasserts or clears (e.g. sets to 0) the flush acknowledgement signal (flush_ack).

Responsive to the “load_new_pattern” pulse being asserted, a new pattern is stored at the selected pattern register 28 and the state machine 26 then clears the “load_new_pattern” signal and restarts a new sequence of bit_select <4:0> signals to cause second selection circuitry 30 to select individual bits of the new pattern and pass them to the ICG 34 to be applied.

Thus, the “flush throttler” signal enables a current pattern being applied to be flushed from the selected pattern register 28 and replaced with a new pattern to be applied before the current pattern completes.

Furthermore, the clock throttler circuitry 1 may provide one or more signals about the operation of the clock throttler circuitry 1 to external circuitry or processes. For example, latch circuitry 40 receives the index signal also provided to the first selection circuitry 23 and, responsive to the “load_new_pattern” pulse, generates confirmation signal 41 (“index_cur”) to confirm the pattern that is currently being applied, where the confirmation signal 41 (“index_cur”) is output.

As further example, when the first and second selection circuitry of the clock throttler circuitry 1 is bypassed, a bypass currently enabled signal “bypass_en_cur” may be provided at output 16. As further example, the state machine 26 may also provide a flush acknowledgement signal (flush_ack) to the mitigation state machine.

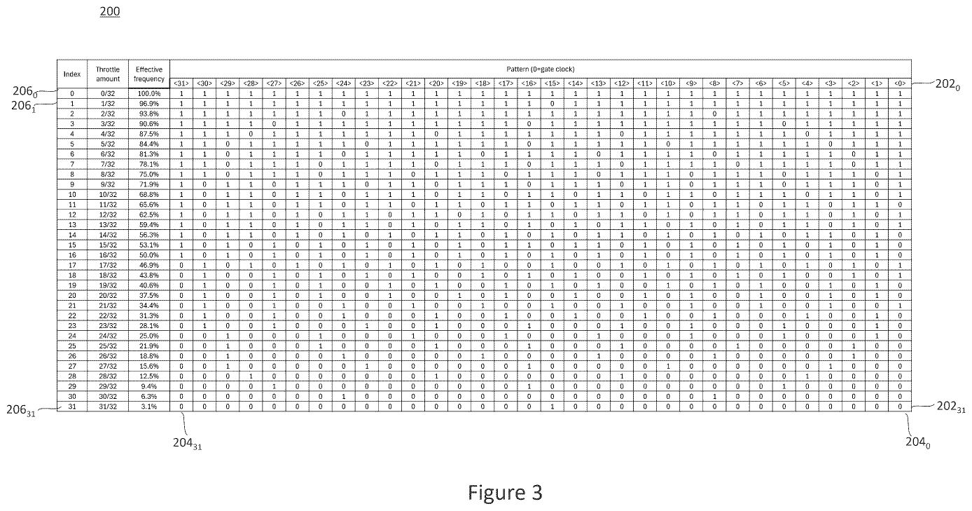

FIG. 3 schematically shows an example table 200 comprising 32 rows of patterns 202₀ to 202₃₁ in accordance with the present techniques.

The patterns in FIG. 3 are depicted as 32-bit patterns, each row having 32 bits 204₀ to 204₃₁. However, the claims are not limited in this respect and patterns of other sizes may be used, and the claims are not limited in a particular size of the patterns. Furthermore, when a different sized pattern is used then the size/values of the various signals required to identify that pattern (e.g. the index <X:0> signal; index_cur<Y:0> signal) and/or the individual bits in that pattern (e.g. the bit_select <Z:0> signal) may also be changed accordingly.

As depicted in FIG. 3, each pattern may be identified by a corresponding pattern identifier, which in the present illustrative examples comprises an index value 206₀ to 206₃₁, where the index value may be specified in the pattern identifier (index <4:0>) signal received at the clock throttler circuitry.

Each bit of the respective patterns in the table of FIG. 3 has a value of 1 or 0, where when a bit having a value 1 is provided to an ICG and applied thereat, the ICG will pass a pulse of a clock signal (e.g. the clock input signal (clkin) depicted in FIG. 1) and when a bit having a value 0 is provided to an ICG and applied thereat, the ICG will gate a pulse of a clock signal (e.g. the clock input signal (clkin) depicted in FIG. 1), thereby throttling an effective frequency of the clock output signal.

Using the ICG to throttle the clock input signal does not affect the minimum width of the clock pulses or the minimum clock period of the pulses. Rather it is the effective frequency of the clock output signal that is throttled, where one or more pulses in the clock input signal may be gated responsive to bits in a pattern to reduce the number of corresponding pulses in the clock output signal over the length of the clock input signal to which the pattern was applied.

Thus throttling the effective frequency of a clock output signal rather than throttling the actual frequency of the clock output signal may address an event but may not impact/affect any timing-related signoff checks performed using that clock output signal.

Applying a 32-bit pattern of all 1s (i.e. the pattern at index 0 (206₀)) will result in the ICG passing all of the clock input signals responsive to pattern corresponding to index 0. Thus, applying pattern 0 will not have any throttle effect on the clock input signal.

Applying the 32-bit pattern at index 1 (206₁) will result in the ICG passing all but one of the clock input signals responsive to pattern at index 1 (206₁). Thus, applying the pattern at index 1 (206₁) will throttle the clock input signal to the ICG by approximately 3.1% to provide an effective frequency of 96.9% for the resulting clock output signal.

Similarly, applying the 32-bit pattern at index 31 (206₃₁) will result in the ICG gating all but one of the clock input signals responsive to pattern at index 31 (206₃₁). Thus, applying the pattern at index 31 (206₃₁) will throttle the clock input signal to the ICG by approximately 96.9% to provide an effective frequency of 3.1% for the resulting clock output signal.

Thus, gating a clock input signal responsive to a single bit of a 32 bit pattern will have a throttle rate of ˜3.1% on the effective frequency of the resulting clock output signal, and each additional bit will increase the throttle rate by ˜3.1% on the effective frequency of the resulting clock output signal.

Different patterns can be applied consecutively to achieve different throttle rates. For example, for the 32-bit pattern depicted in FIG. 3, applying index 1 followed by index 2 will provide a throttle rate of approximately 4.6% on the effective frequency of the resulting clock output signal.

It will be appreciated that the clock speed is not throttled when gating one or more pulses, rather it is the effective frequency that is throttled.

As depicted in FIG. 3 the zeros (0's) are distributed equally in each of the patterns. However the claims are not limited in this respect and different positions of the 1's and 0's can be used for each pattern. Taking the pattern at index 16 as an example, rather than having a sequence of 1, 0, 1, 0 . . . to provide a throttling rate of approximately 50% on the effective frequency, the pattern may be modified to have a pattern of sixteen bits each with a value of 1 followed by sixteen bits each with a value of 0. In a further example, a pattern of 100110100110 . . . may be used to provide the same throttle rate on the effective frequency (i.e. approximately 50%).

In an illustrative example, a particular pattern of 1s and 0's may, when applied, affect performance of the system (e.g. a pattern may ignite resonance frequencies in a power distribution network). Thus, the 1s and 0's in a particular pattern may be adjusted/programmed (e.g. via firmware) to avoid any negative effects as required.

Looking again at FIG. 2, the first selection circuitry 23 is to select a pattern along a particular row 202₀ to 202₃₁ responsive to the pattern identifier (index <4:0>) signal while the second selection circuitry 30 is to select individual bits along the columns 204₀ to 204₃₁ of the selected pattern responsive to the sequence of bit_select <4:0> signals from the state machine 26.

As set out above, the patterns are not limited to 32-bit patterns. When a 64-bit pattern is used, gating an clock input signal responsive to a single bit of a 64 bit pattern will have a throttle rate of ˜1.55% on the effective frequency of the resulting clock output signal, and each additional bit will increase the throttle rate on the effective frequency of the resulting clock output signal by ˜1.55%.

Therefore, the clock throttler circuit can throttle the clock output signal to respond to one or more events, providing different levels of throttling as required.

As an illustrative example, the index provided to the clock throttler circuitry may be dependent the type of event, where when an overcurrent event is detected a first throttle rate (e.g. ˜15%) may be required so a pattern identifier (index <4:0>) signal identifies, via an index value therein, a pattern in a register of a first storage (e.g. first register bank) to be applied. In FIG. 3, the index value may identify the pattern corresponding to Index 5 which provides 15.5% throttle rate. Similarly, where an overtemperature event is detected then a second throttle rate (e.g. 10%) may be required, where the index value may identify the pattern corresponding to Index 3 which provides ˜9.4% throttle rate.

The index can also be provided based on the severity of the warning event. For example, an overtemperature warning at 85° C. may require a throttle rate of ˜10% (Index 3); an overtemperature warning at 90° C. may require a throttle rate of ˜15% (Index 5); an overtemperature warning at 95° C. may require a throttle rate of ˜20% (Index 7); and an overtemperature warning at 100° C. may require a throttle rate of ˜30% (Index 9).

The warning events may be received from a corresponding subsystem receiving the clock output signal from the clock throttler circuit, where a CPU may have one or more temperature sensors to generate the overtemperature warnings and a power management integrated circuit (PMIC) may provide the overcurrent warnings.

The mitigation state machine 2ₙ can then control the clock throttler circuitry 1 to provide a throttle rate dependent on the warning event, and when the warning event is cleared the mitigation state machine can control the throttling functionality to mitigate any adverse effects of reducing the throttle rate.

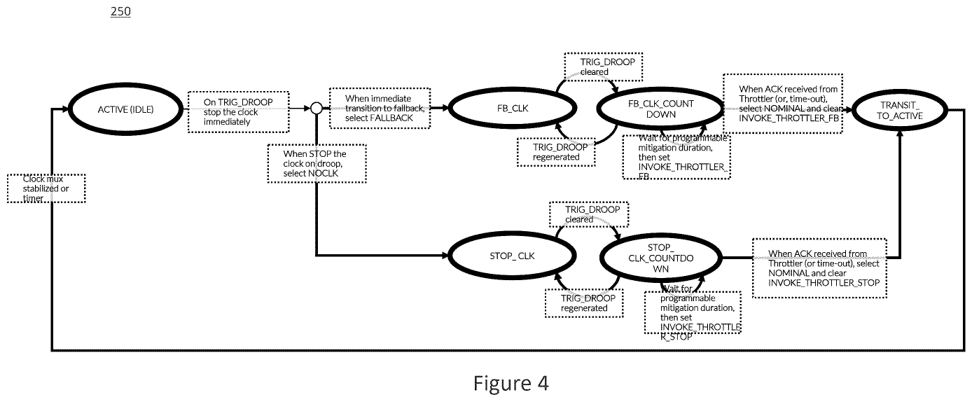

FIG. 4 schematically shows the operations 250 of the state machine circuitry of the droop mitigator circuitry in accordance with the present techniques.

In a first state the state machine 105 is in an ACTIVE(IDLE) state. When a droop trigger signal (TRIG_DROOP) is received from the droop detector NOMINAL clock is stopped using the stopclk_nominal signal 108. When, responsive to the droop trigger signal (TRIG_DROOP), the FALLBACK clock is required then the clock multiplexer circuitry selects the FALLBACK clock and transitions to FB_CLK state, where the FALLBACK clock is output as the droop mitigated clock signal (clk_droop_mitigated). When the droop trigger signal is cleared the state machine operation transitions to FB_CLK_COUNTDOWN where the state machine waits for a programmable duration, and when the programmable duration expires (E.g. counts down 0 or other value) then the INVOKE_THROTTLER_FB signal 5a is provided to the mitigation state machine 2ₙ to control the clock throttler circuitry accordingly. When the acknowledgment INVOKE_THROTTLER_FB_ACK signal 5b is received from the mitigation state machine 2ₙ then the clock multiplexer circuitry selects the NOMINAL clock as the droop mitigated clock and transitions to TRANSIT_TO_ACTIVE state. In a further embodiment, rather than waiting for an acknowledgment signal, the clock multiplexer circuitry could select the NOMINAL clock and transition to TRANSIT_TO_ACTIVE state after waiting a set time after providing the INVOKE_THROTTLER_FB signal.

When the clock multiplexer circuitry is stabilized and the NOMINAL clock is output as the droop mitigated clock signal, the state machine operation transitions to ACTIVE(IDLE).

When, responsive to the droop trigger signal (TRIG_DROOP) no clock signal is required then the clock multiplexer circuitry selects the NOCLK clock and transitions to STOP_CLK state, where no clock pulses are output in the droop mitigated clock signal (clk_droop_mitigated). When the droop trigger signal is cleared the state machine operation transitions to STOP_CLK_COUNTDOWN where the state machine waits for a programmable duration, and when the programmable duration expires (E.g. counts down 0 or other value) then the INVOKE_THROTTLER_STOP signal is provided to the mitigation state machine 2ₙ to control the clock throttler circuitry accordingly.

When the acknowledgment INVOKE_THROTTLER_STOP_ACK signal is received from the mitigation state machine 2ₙ then the clock multiplexer circuitry selects the NOMINAL clock as the droop mitigated clock and transitions to TRANSIT_TO_ACTIVE state. In a further embodiment, rather than waiting for an acknowledgment signal, the clock multiplexer circuitry could select the NOMINAL clock and transition to TRANSIT_TO_ACTIVE state after waiting a set time after providing the INVOKE_THROTTLER_STOP signal.

When the clock multiplexer circuitry is stabilized and the NOMINAL clock is output as the droop mitigated clock signal, the state machine operation transitions to ACTIVE(IDLE).

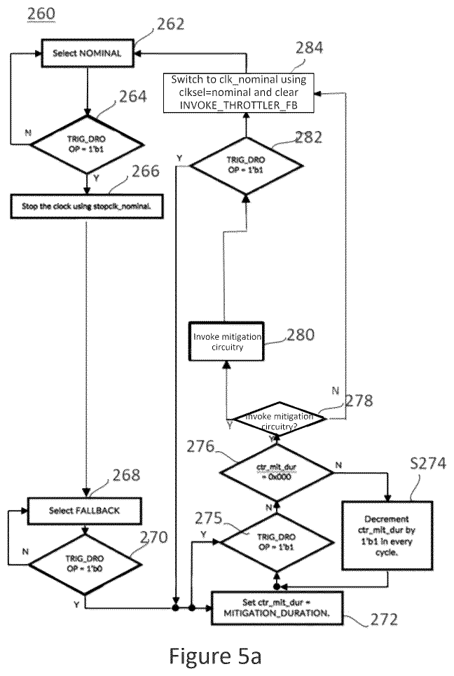

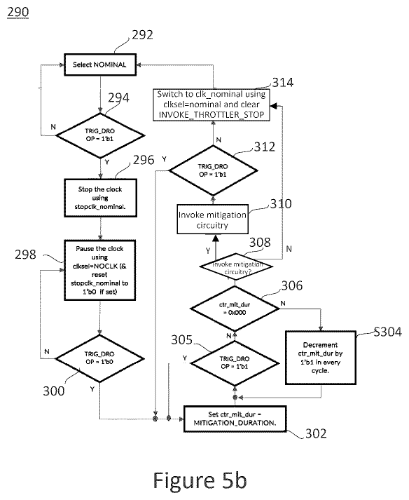

FIG. 5a schematically shows a simplified flow diagram of a method 260 of operation of the system for droop mitigation according to an implementation of the present techniques.

At S262 the NOMINAL clock is output as the droop mitigated clock.

At S264, responsive to a detected droop event, a droop trigger signal is asserted, and at S266, the NOMINAL clock is stopped.

At S268 the FALLBACK clock is selected and output at as the droop mitigated clock until it is determined at S270 that the droop trigger signal is deasserted (or cleared)—to indicate that the detected droop event is cleared.

At S272 when the droop trigger signal is cleared a timer is set for a programmable duration. The timer is, at S274, decremented every cycle and when no further droop trigger signal is asserted (S275) before the programmable duration expires (S276) (E.g. counts down 0 or other value) it is, at S278, determined whether or not to use the modulation circuitry. For example, some systems may not have modulation circuitry or it may be disabled due to user requirements.

In an embodiment, when the mitigator circuitry is not available, the NOMINAL clock is selected and at S284 output as the droop mitigated clock and provided to a subsystem. However, transitioning from the FALLBACK clock to the NOMINAL clock without any throttling may result in adverse effects, e.g. such operation may risk a further droop event at the subsystem.

In an embodiment when, at S278, it's determined to use the modulation circuitry then the modulation circuitry 100 is invoked (S280) where, as above in FIG. 4, an INVOKE_THROTTLER_FB signal may be provided to the mitigation state machine to control the clock throttler circuitry. When a further trigger droop event is detected (S282) then the flow returns to S272, otherwise at S284 the NOMINAL clock is selected as the droop mitigated clock and provided to the clock throttler circuit to control the throttling thereof in accordance with the detected event and the INVOKE_THROTTLER_FB signal 5a is cleared. Thus, clock throttle circuit can throttle the effective frequency of the NOMINAL clock to ramp up the effective frequency so the subsystem receiving the NOMINAL clock is not operating at the 100% effective frequency as soon as the clock provided thereto is switched from the FALLBACK clock to the NOMINAL clock.

FIG. 5b schematically shows a simplified flow diagram of a method 290 of operation of the system for droop mitigation according to an implementation of the present techniques.

At S292 the NOMINAL clock is output as the droop mitigated clock.

At S294, responsive to a detected droop event, a droop trigger signal is asserted, and at S296, the NOMINAL clock is stopped.

At S298 the NOMINAL clock is paused until it is determined at S300 that the droop trigger signal is deasserted (cleared)—to indicate that the detected droop event is cleared.

At S302 when the droop trigger signal is cleared a timer is set for a programmable duration. The timer is, at S304, decremented every cycle and when no further droop trigger signal is asserted (S305) before the programmable duration expires (S306) (E.g. counts down 0 or other value) it is, at S308, determined whether or not to use the modulation circuitry.

In an embodiment, when the mitigator circuitry is not available, the NOMINAL clock is selected and at S314 output as the droop mitigated clock and provided to a subsystem. However, transitioning from the STOP clock signal to the NOMINAL clock signal without any throttling may result in adverse effects, e.g. such operation may risk a repeat droop event at the subsystem.

In an embodiment when, at S308, it's determined to use the mitigator circuitry then the modulation circuitry 100 is invoked where, as above in FIG. 4, an INVOKE_THROTTLER_STOP signal may be provided to the mitigation state machine to control the clock throttler circuitrycircuitry. When a further trigger droop event is detected (S312) then the flow returns to S302, otherwise at S314 the NOMINAL clock is selected as the droop mitigated clock and provided to the clock throttler circuit to control the throttling thereof in accordance with the detected event and the INVOKE_THROTTLER_STOP signal is cleared. Thus, clock throttle circuit can throttle the effective frequency of the NOMINAL clock to ramp up the effective frequency so the subsystem receiving the NOMINAL clock is not operating at the 100% effective frequency as soon as the clock provided thereto is switched from no clock signal to NOMINAL.

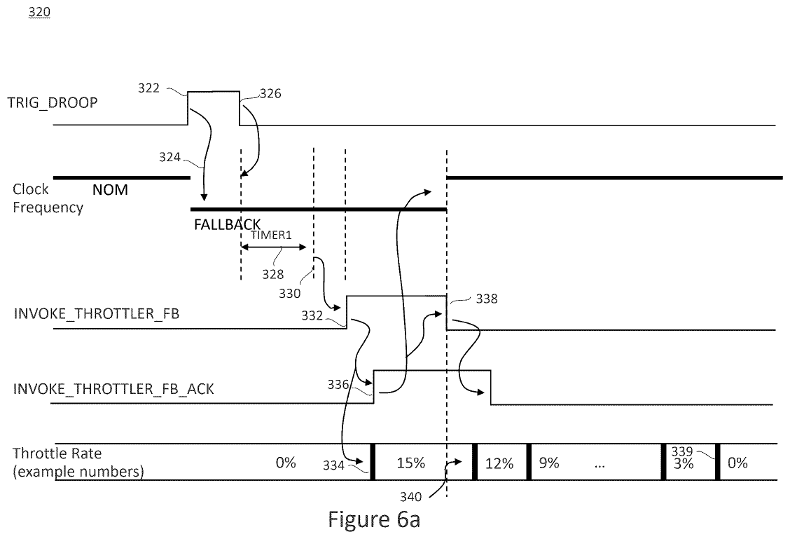

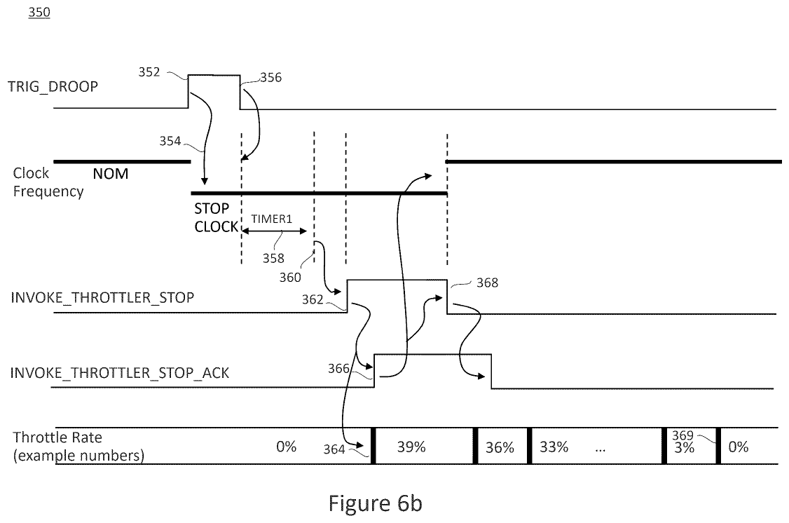

FIG. 6a schematically shows a waveform diagram 320 for invoking the clock throttler circuitry of FIG. 1 according to an implementation of the present techniques.

As depicted at 322, when a droop event is detected the TRIG_DROOP signal is asserted, and at 324 the FALLBACK CLOCK is selected as the droop mitigated clock provided to the modulation circuitry.

When, at 326, the TRIG_DROOP signal is deasserted or cleared (e.g. when the droop event is cleared), the programmable timer is started at 328, and is decremented every cycle while no further droop event is detected.

When, at 330 the programmable timer counts down (or counts up) to a specified value then at 332 the droop mitigator circuitry provides an INVOKE_THROTTLER_FB signal to the modulation circuitry.

The INVOKE_THROTTLER_FB signal causes a selected pattern to be applied to achieve a desired throttle rate (e.g. where the mitigation state machine 2n provides an Index value corresponding to the selected pattern to the clock throttler circuit). When the selected pattern is selected, the mitigation state machine 2n provides the INVOKE_THROTTLER_FB_ACK signal 336 which confirms the selected pattern is selected to be applied.

When the droop event is cleared the INVOKE_THROTTLER_FB signal is cleared at 338, and the mitigation state machine applies the selected pattern to the NOMINAL clock to achieve the desired throttle rate (depicted as 15% in FIG. 6a). The clock throttler circuit is controlled to ramp down the throttle rate over a plurality of throttle levels. In the illustrative example, the throttle rate is reduced from 15% (at 334) to 0% (at 339) over multiple throttle levels. It will be appreciated that the reduction in throttle levels in FIG. 6a is exemplary only and the reduction may be in any number of steps of throttle level as required (e.g. by an application).

As depicted in FIG. 6a, there may be a period (340) that the clock throttler circuit throttles the effective frequency of the FALLBACK clock when it is provided as the droop mitigated clock signal before the switch to the NOMINAL clock. In that case the throttled FALLBACK clock is provided to the subsystem.

Such functionality provides for ramping up the effective frequency of the droop mitigated clock signal provided to a subsystem when the droop mitigated clock signal switches from the FALLBACK clock to the NOMINAL clock, thereby providing a gradual recovery from the FALLBACK clock to the NOMINAL clock.

FIG. 6b schematically shows a waveform diagram 350 for invoking the clock throttler circuitry of FIG. 1 according to an implementation of the present techniques.

As depicted at 352, when a droop event is detected the TRIG_DROOP signal is asserted, and at 354 the NOMINAL CLOCK is stopped.

When, at 356, the TRIG_DROOP signal is deasserted or cleared (e.g. when the droop event is cleared), the programmable timer is started at 358, and is decremented every cycle while no further droop event is detected.

When, at 360 the programmable timer counts down (or counts up) to a specified value then at 362 the droop mitigator circuitry provides an INVOKE_THROTTLER_STOP signal to the modulation circuitry.

The INVOKE_THROTTLER_STOP signal causes a selected pattern to be applied to achieve a desired throttle rate (e.g. where the mitigation state machine 2ₙ provides an Index value corresponding to the selected pattern to the clock throttler circuit). When the selected pattern is selected, the mitigation state machine 2ₙ provides the INVOKE_THROTTLER_STOP_ACK signal 366 which confirms the selected pattern is selected to be applied.

When the droop event is cleared the INVOKE_THROTTLER_STOP signal is cleared at 368, and the mitigation state machine applies the selected pattern to the NOMINAL clock to achieve the desired throttle rate (depicted as 39% in FIG. 6b). The clock throttler circuit is controlled to ramp down the throttle rate over a plurality of throttle levels. In the illustrative example, the throttle rate is reduced from 39% (at 364) to 0% (at 369) over multiple levels. It will be appreciated that the reduction in throttle levels in FIG. 6b is exemplary only and the reduction may be in any number of steps of throttle level as required (e.g. by an application).

Such functionality provides for ramping up the effective frequency of the droop mitigated clock signal provided to a subsystem when the droop mitigated clock signal switches from restarts the NOMINAL clock, thereby providing a gradual recovery from the stopped clock to the NOMINAL clock.

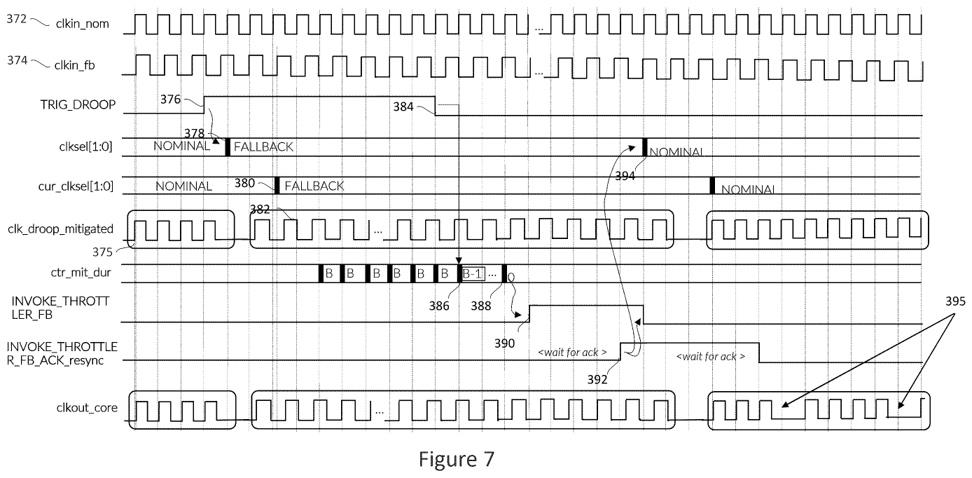

FIG. 7 schematically shows a signal diagram 300 for the system for droop mitigation depicted in FIG. 1.

As depicted, the NOMINAL clock signal (clkin_nom) 372 has a higher frequency relative to the FALLBACK clock signal (clkin_fb) 374. The NOMINAL clock signal 372 may be provided by, for example, a first phased-locked loop (PLL) clock source and the FALLBACK clock signal (clkin_fb) 374 may be provided by a second phased-locked loop (PLL) clock source.

In operation, when the NOMINAL clock is provided as the droop mitigated clock signal (clk_droop_mitigated) (375) and a droop event is detected, then an asynchronous warning signal TRIG_DROOP is asserted (376) at the droop mitigator circuitry (e.g. from droop detection circuitry), where the clock select signal “clksel[1:0]” is updated (378) to indicate to the clock multiplexer circuitry 103 that the FALLBACK clock should be selected as the droop mitigated clock.

At 380 the current clksel signal “cur_clksel[1:0]” is synchronised with the FALLBACK clock, and the FALLBACK clock is output as the droop mitigated clock signal (clk_droop_mitigated) (e.g. provided to modulation based mitigator circuitry).

When the droop event is cleared, then the warning signal TRIG_DROOP is deasserted or cleared (384), and a programmable timer is started at 386, and is decremented every cycle while no further droop event is detected.

When the programmable timer counts down (or counts up) to a specified value (388) then the droop mitigator circuitry provides an INVOKE_THROTTLER_FB signal to the modulation circuitry (390) to select a pattern to apply to the NOMINAL clock in order to achieve a desired throttle rate.

An acknowledgement signal INVOKE_THROTTLER_FB_ACK_resync (synchrohnised with the NOMINAL clock) is invoked (392) to indicate that the pattern is selected to be applied by the clock throttler circuitry, and the clock select signal (clksel[1:0]) is updated (394) to indicate to the clock multiplexer circuitry 103 that the NOMINAL clock should be selected as the droop mitigated clock. As above, rather than waiting for the acknowledgement signal, the clock select signal (clksel[1:0]) could be updated responsive to a timer expiring.

The current clksel signal (cur_clksel[1:0]) is updated 396 and the NOMINAL clock is output as the droop mitigated clock signal (clk_droop_mitigated) (e.g. provided to modulation based mitigator circuitry).

Thus the present techniques provide modulation circuitry which can be used to throttle a clock signal responsive to a detected event, and to control the amount of throttling when a new event occurs or when the detected event is cleared (or addressed). The throttled clock signal (clkout_core) can be provided to an integrated circuit subsystem (e.g. E.g. central processor units (CPU), graphics processor units (GPU), neural processor units (NPU) etc.) (395).

One or more clock throttler circuits may be provided in a data processer system, where such a data processor system may include one or more subsystems.

For example, a data processor unit may have multiple CPU tiles where one or more clock throttler circuits may be provided inside each CPU tile. The functionality can be used to independently control the clock signals supplied to each CPU tile or to each core within a CPU tile.

In an illustrative example, a CPU may comprise a first core running a thread at a high priority from a software perspective (high priority core) and another core running a thread at a lower priority (low priority core). Thus, a pattern of all 1's may be selected and applied to the clock signal provided to the high priority core and a pattern with one or more zeros may be selected and applied to the clock signal of the low priority core to throttle the effective frequency thereof. In this way the data processing system can use one or more clock throttler circuits to provide clock signals having different effective frequencies to different cores, for example, generate less heat in the system.

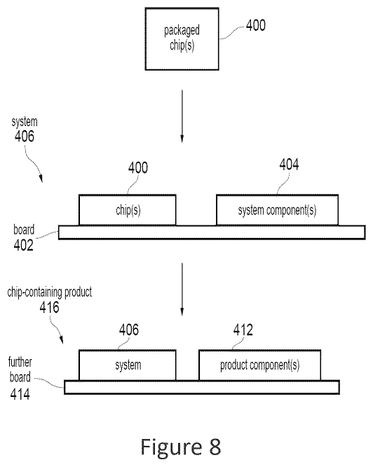

As shown in FIG. 8, one or more packaged chips 400, with the circuitry described above implemented on one chip or distributed over two or more of the chips, are manufactured by a semiconductor chip manufacturer. In some examples, the chip product 400 made by the semiconductor chip manufacturer may be provided as a semiconductor package which comprises a protective casing (e.g. made of metal, plastic, glass or ceramic) containing the semiconductor devices implementing the circuitry described above and connectors, such as lands, balls or pins, for connecting the semiconductor devices to an external environment. Where more than one chip 400 is provided, these could be provided as separate integrated circuits (provided as separate packages), or could be packaged by the semiconductor provider into a multi-chip semiconductor package (e.g. using an interposer, or by using three-dimensional integration to provide a multi-layer chip product comprising two or more vertically stacked integrated circuit layers).

In some examples, a collection of chiplets (i.e. small modular chips with particular functionality) may itself be referred to as a chip. A chiplet may be packaged individually in a semiconductor package and/or together with other chiplets into a multi-chiplet semiconductor package (e.g. using an interposer, or by using three-dimensional integration to provide a multi-layer chiplet product comprising two or more vertically stacked integrated circuit layers).

The one or more packaged chips 400 are assembled on a board 402 together with at least one system component 404 to provide a system 406. For example, the board may comprise a printed circuit board. The board substrate may be made of any of a variety of materials, e.g. plastic, glass, ceramic, or a flexible substrate material such as paper, plastic or textile material. The at least one system component 404 comprise one or more external components which are not part of the one or more packaged chip(s) 400. For example, the at least one system component 404 could include, for example, any one or more of the following: another packaged chip (e.g. provided by a different manufacturer or produced on a different process node), an interface module, a resistor, a capacitor, an inductor, a transformer, a diode, a transistor and/or a sensor.

A chip-containing product 416 is manufactured comprising the system 406 (including the board 402, the one or more chips 400 and the at least one system component 404) and one or more product components 412. The product components 412 comprise one or more further components which are not part of the system 406. As a non-exhaustive list of examples, the one or more product components 412 could include a user input/output device such as a keypad, touch screen, microphone, loudspeaker, display screen, haptic device, etc.; a wireless communication transmitter/receiver; a sensor; an actuator for actuating mechanical motion; a thermal control device; a further packaged chip; an interface module; a resistor; a capacitor; an inductor; a transformer; a diode; and/or a transistor. The system 406 and one or more product components 412 may be assembled on to a further board 414.

The board 402 or the further board 414 may be provided on or within a device housing or other structural support (e.g. a frame or blade) to provide a product which can be handled by a user and/or is intended for operational use by a person or company.

The system 406 or the chip-containing product 416 may be at least one of: an end-user product, a machine, a medical device, a computing or telecommunications infrastructure product, or an automation control system. For example, as a non-exhaustive list of examples, the chip-containing product could be any of the following: a telecommunications device, a mobile phone, a tablet, a laptop, a computer, a server (e.g. a rack server or blade server), an infrastructure device, networking equipment, a vehicle or other automotive product, industrial machinery, consumer device, smart card, credit card, smart glasses, avionics device, robotics device, camera, television, smart television, DVD players, set top box, wearable device, domestic appliance, smart meter, medical device, heating/lighting control device, sensor, and/or a control system for controlling public infrastructure equipment such as smart motorway or traffic lights.

As will be appreciated by one skilled in the art, the present technology may be embodied as a method, a circuit or a computer readable medium comprising data and imperatives to cause construction of a circuit. Accordingly, the present technique may take the form of an entirely hardware embodiment, an entirely software embodiment, or an embodiment combining software and hardware. Where the word “component” is used, it will be understood by one of ordinary skill in the art to refer to any portion of any of the above embodiments.

Concepts described herein may be embodied in computer-readable code for fabrication of an apparatus that embodies the described concepts. For example, the computer-readable code can be used at one or more stages of a semiconductor design and fabrication process, including an electronic design automation (EDA) stage, to fabricate an integrated circuit comprising the apparatus embodying the concepts. The above computer-readable code may additionally or alternatively enable the definition, modelling, simulation, verification and/or testing of an apparatus embodying the concepts described herein.

For example, the computer-readable code for fabrication of an apparatus embodying the concepts described herein can be embodied in code defining a hardware description language (HDL) representation of the concepts. For example, the code may define a register-transfer-level (RTL) abstraction of one or more logic circuits for defining an apparatus embodying the concepts. The code may define a HDL representation of the one or more logic circuits embodying the apparatus in Verilog, SystemVerilog, Chisel, or VHDL (Very High-Speed Integrated Circuit Hardware Description Language) as well as intermediate representations such as FIRRTL. Computer-readable code may provide definitions embodying the concept using system-level modelling languages such as SystemC and SystemVerilog or other behavioural representations of the concepts that can be interpreted by a computer to enable simulation, functional and/or formal verification, and testing of the concepts.

Additionally or alternatively, the computer-readable code may define a low-level description of integrated circuit components that embody concepts described herein, such as one or more netlists or integrated circuit layout definitions, including representations such as GDSII. The one or more netlists or other computer-readable representation of integrated circuit components may be generated by applying one or more logic synthesis processes to an RTL representation to generate definitions for use in fabrication of an apparatus embodying the invention. Alternatively or additionally, the one or more logic synthesis processes can generate from the computer-readable code a bitstream to be loaded into a field programmable gate array (FPGA) to configure the FPGA to embody the described concepts. The FPGA may be deployed for the purposes of verification and test of the concepts prior to fabrication in an integrated circuit or the FPGA may be deployed in a product directly.

The computer-readable code may comprise a mix of code representations for fabrication of an apparatus, for example including a mix of one or more of an RTL representation, a netlist representation, or another computer-readable definition to be used in a semiconductor design and fabrication process to fabricate an apparatus embodying the invention. Alternatively or additionally, the concept may be defined in a combination of a computer-readable definition to be used in a semiconductor design and fabrication process to fabricate an apparatus and computer-readable code defining instructions which are to be executed by the defined apparatus once fabricated.

Such computer-readable code can be disposed in any known transitory computer-readable medium (such as wired or wireless transmission of code over a network) or non-transitory computer-readable medium such as semiconductor, magnetic disk, or optical disc. An integrated circuit fabricated using the computer-readable code may comprise components such as one or more of a central processing unit, graphics processing unit, neural processing unit, digital signal processor or other components that individually or collectively embody the concept.

In the present application, the words “configured to...” are used to mean that an element of an apparatus has a configuration able to carry out the defined operation. In this context, a “configuration” means an arrangement or manner of interconnection of hardware or software. For example, the apparatus may have dedicated hardware which provides the defined operation, or a processor or other processing device may be programmed to perform the function. “Configured to” does not imply that the apparatus element needs to be changed in any way in order to provide the defined operation.

In the present application, lists of features preceded with the phrase “at least one of” mean that any one or more of those features can be provided either individually or in combination. For example, “at least one of: [A], [B] and [C]” encompasses any of the following options: A alone (without B or C), B alone (without A or C), C alone (without A or B), A and B in combination (without C), A and C in combination (without B), B and C in combination (without A), or A, B and C in combination.

Although illustrative embodiments of the invention have been described in detail herein with reference to the accompanying drawings, it is to be understood that the invention is not limited to those precise embodiments, and that various changes and modifications can be effected therein by one skilled in the art without departing from the scope of the invention as defined by the appended claims.

1. A method of droop mitigation, the method performed at a system to select a first clock signal or a second clock signal to be provided to a subsystem, the method comprising:
receiving, from a droop detector, a trigger signal indicative of a droop event at the subsystem;
invoking modulation circuitry to throttle the selectable clock signal in accordance with the event;
selecting the first clock signal;
providing, to the modulation circuitry, the first clock signal to be throttled.

2. The method of claim 1, further comprising:
selecting, responsive to the trigger signal being asserted, the second clock signal;
providing the second clock signal to the subsystem.

3. The method of claim 2, further comprising:
setting, responsive to the trigger signal being deasserted, a timer;
invoking, responsive to the timer reaching a specified value, the modulation circuitry.

4. The method of claim 3, further comprising:
decrementing or incrementing the timer every clock cycle until the timer reaches the specified value.

5. The method of claim 1, further comprising:
providing the first clock signal to the subsystem;
stopping, responsive to the trigger signal, the first clock signal.

6. The method of claim 4, further comprising:
setting, responsive to the trigger signal being deasserted, a timer;
invoking, responsive to the timer reaching a specified value, the modulation circuitry.

7. The method of claim 6, further comprising:
decrementing the timer or incrementing the time every clock cycle until the timer reaches the specified value.

8. The method of claim 1, where the first clock signal has a higher frequency relative to the second clock signal.

9. A method of droop mitigation, the method performed at a system to throttle a clock signal, the method comprising:
receiving, from droop mitigator circuitry, a request to apply a target throttle rate;
receiving, from the droop mitigator circuitry, the clock signal;
applying a first throttle rate to the received clock signal;
providing the clock signal with the first throttle rate to a subsystem.

10. The method of claim 9, further comprising: ramping down the throttle rate from first throttle rate to the target throttle rate.

11. The method of claim 9, where the clock throttler circuitry comprises clock gate circuitry, where the clock gate circuitry is to pass or gate pulses of the clock signal responsive to a pulse enable signal.

12. The method of claim 11, where applying the first throttle rate comprises gating one or more pulses of the clock signal at a clock throttler circuit and.

13. The method of claim 11, where applying the target throttle rate comprises passing all pulses of the clock signal at a clock throttler circuit.

14. The method of claim 11, where applying the throttle rate comprises applying a first pattern of bits having a first value or a second value, where applying a bit having a first value as the pulse enable signal is to pass a pulse of the clock signal and where applying a bit having a second value as the pulse enable signal is to gate a pulse of the clock signal.

15. The method of claim 14, where applying the target throttle rate comprises applying a pattern of bits each having the first value and/or where applying the first target throttle rate comprises applying a pattern of bits comprising at least one bit having the second value.

16. Circuitry to perform droop mitigation, the circuitry comprising:
a first component configured to:
receive, from a second component, a request to apply a target throttle rate;
receive, from the second component, a clock signal;
apply a first throttle rate to the received clock signal;
provide the clock signal with the first throttle rate to a subsystem.

17. The circuitry of claim 16, where the first component is configured to:
reduce the throttle rate applied to the clock signal from the first throttle rate to the target throttle rate over one or more throttle levels;
provide the clock signal with the target throttle rate to the subsystem.

18. The circuitry of claim 16, comprising:
the second component, where the second component is configured to:
receive a trigger signal indicative of a droop event at the subsystem;
send the request to the first component responsive to the trigger signal;
select the clock signal from two or more clock signals;
provide, to the first component, the selected clock signal to be throttled.

19. A system comprising:
the circuitry of claim 16, implemented in at least one packaged chip;
at least one system component; and
a board,
wherein the at least one packaged chip and the at least one system component are assembled on the board.

20. A chip-containing product comprising the system of claim 19 assembled on a further board with at least one other product component.
